(19) United States
(12) Patent Application Publication
(10) Pub. No.: US 2014/0362538 A1
(43) Pub. Date: Dec. 11, 2014

(54) FASTENING DEVICE FOR HEAT SINK

(71) Applicants: HON HAI PRECISION INDUSTRY CO., LTD., NEW TAIPEI (TW); HONG FU JIN PRECISION INDUSTRY (SHENZHEN) CO., LTD., SHENZHEN (CN)

(72) Inventor: SHAO-GUANG SU, Shenzhen (CN)

(73) Assignees: HON HAI PRECISION INDUSTRY CO., LTD., NEW TAIPEI (TW); HONG FU JIN PRECISION INDUSTRY (SHENZHEN) CO., LTD., SHENZHEN (CN)

(21) Appl. No.: 14/067,903

(22) Filed: Oct. 30, 2013

(30) Foreign Application Priority Data
Jun. 11, 2013 (CN) 2013102302321

(51) Int. Cl. H05K 7/20

(52) U.S. Cl. CPC H05K 7/2039
USPC 361/720

(57) ABSTRACT

A fastening device for a heat sink includes a circuit board, four fasteners, two slide poles, four resilient members, and two wrenches. An electronic component is attached to the circuit board. The protrusions extend up from the circuit board. The fasteners are engaged in the protrusions. The slide poles are located at opposite sides of the electronic component, each slide pole is slidably connected to two of the fasteners. The resilient members are connected to the fasteners. The wrenches are pivotably connected to the heat sink. Each wrench includes a hook. When the wrenches are rotated, the hooks abut against bottoms of the slide poles to bias the slide poles to move up and deform the resilient members. When the wrenches are perpendicular to the circuit board, the slide poles enter the hooks and press down the hooks, the wrenches make the heat sink press the electronic component.

### BACKGROUND

1. Technical Field

The present disclosure relates to a device for fastening a heat sink to an electronic component.

2. Description of Related Art

A heat sink is generally mounted to a circuit board by screws to dissipate heat for an electronic component, such as a central processing unit. However, mounting the heat sink to the circuit board with screws requires a screwdriver, which is inconvenient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a fastening device together with a heat sink, wherein the fastening device includes a circuit board, and two wrenches.

FIG. 2 is an inverted view of the circuit board of FIG. 1.

FIG. 3 is an assembled, isometric view of FIG. 1.

FIG. 4 is similar to FIG. 3, but shows a different state of use.

FIG. 5 is a side plan view of one of the wrenches of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

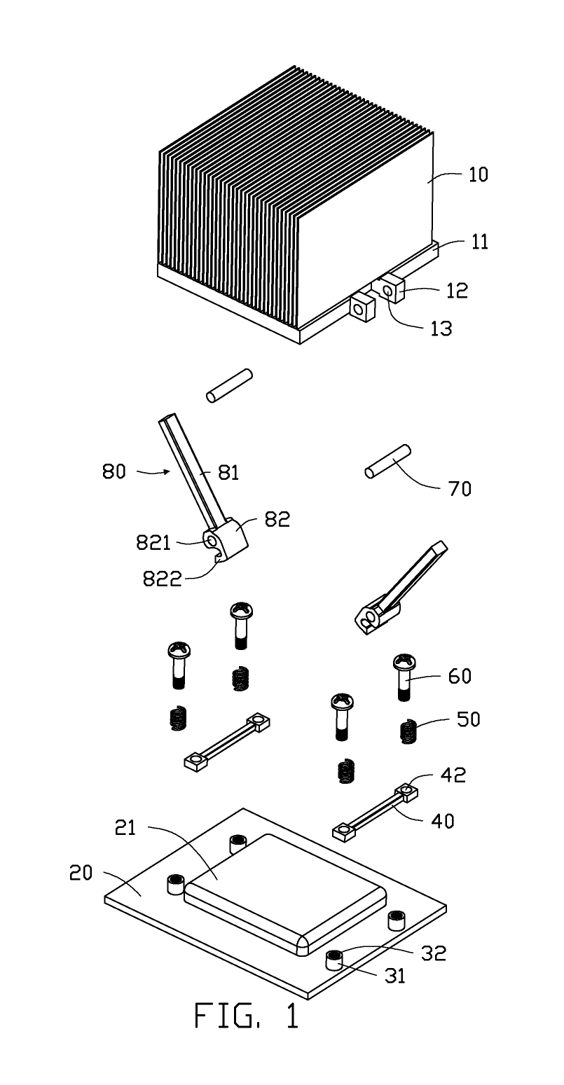

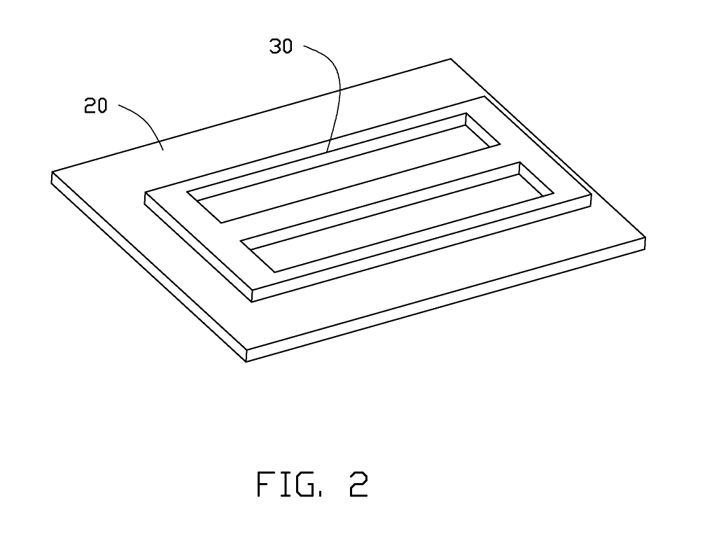

FIGS. 1 and 2 show an embodiment of a fastening device for a heat sink 10. The fastening device includes a circuit board 20, a backplane 30 fastened to a bottom surface of the circuit board 20 for enhancing the strength of the circuit board 20, two slide poles 40, four resilient members 50, four fasteners 60, two pivot shafts 70, and two wrenches 80. In the embodiment, the resilient members 50 are springs. The fasteners 60 are bolts.

Two opposite blocks 12 extend from each of opposite sides of a bottom plate 11 of the heat sink 10. Each block 12 defines a through hole 13.

An electronic component 21 is attached on the circuit board 20. Four protrusions 31 extend up from the circuit board 20, arranged in a rectangle. The electronic component 21 is located among the protrusions 31. Each protrusion 31 axially defines a locking hole 32.

Two through holes 42 are defined in opposite ends of each slide pole 40.

Each wrench 80 includes an operation pole 81, and a pivot segment 82 formed on an end of the operation pole 81. The pivot segment 82 defines a pivot hole 821 extending along a direction perpendicular to the operation pole 81. A hook 822 extends from the pivot segment 82, opposite to the operation pole 81.

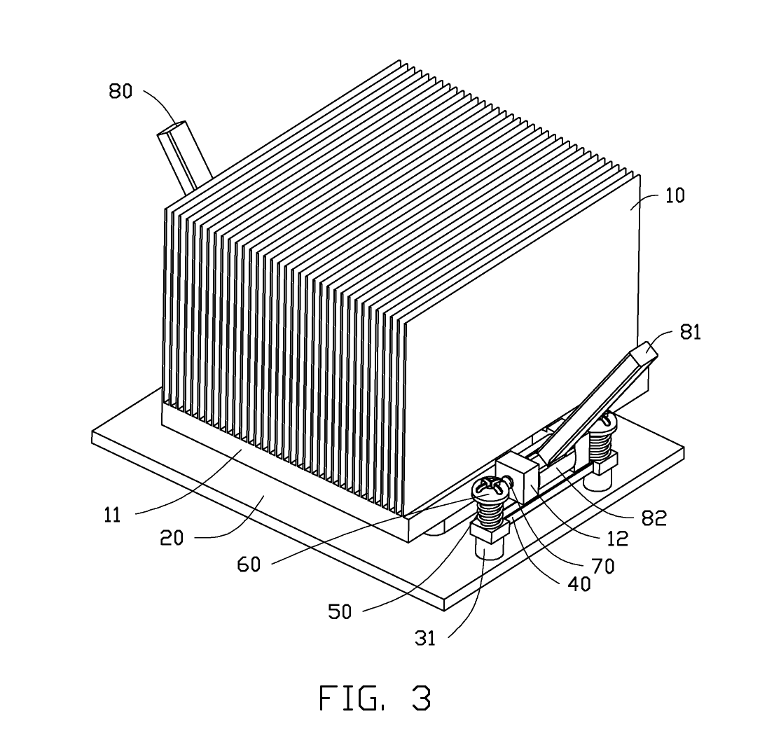

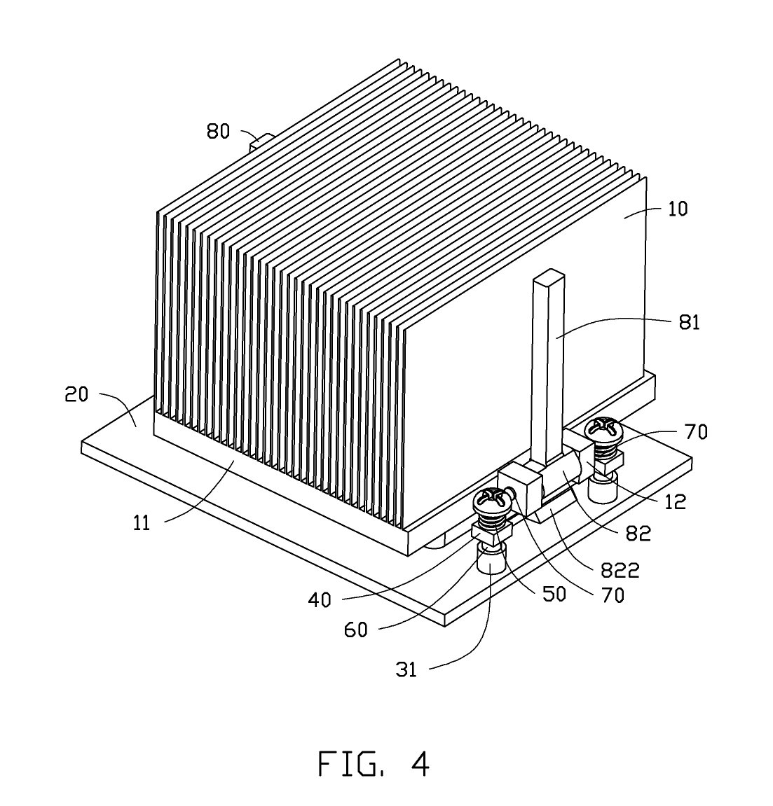

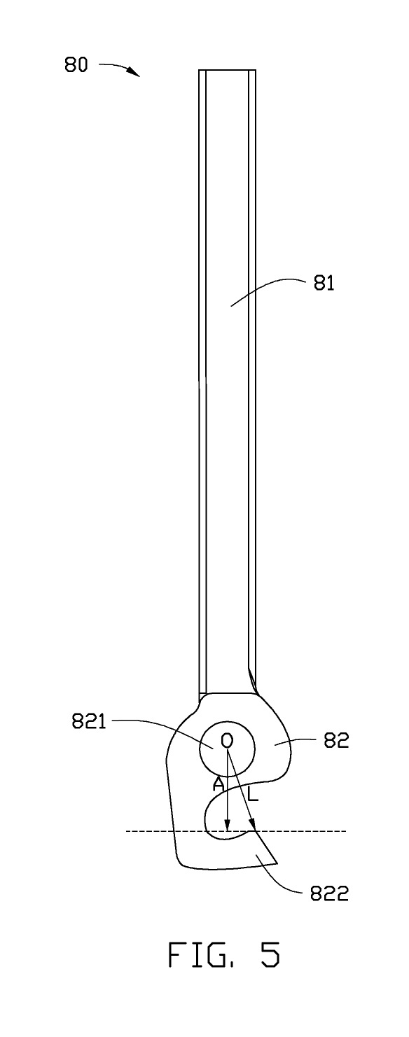

FIGS. 3-5 show that in assembly, one of the slide poles 40 is placed on two of the protrusions 31 located at a side of the electronic component 21, and the other slide pole 40 is placed on the two protrusions 31 located at an opposite side of the electronic component 21. The fasteners 60 extend through the resilient members 50, the through holes 42, and engage in the locking holes 32, to slidably connect the slide poles 40 to the fasteners 60 along an axial direction of the fasteners 60. One of the wrenches 80 is placed between the blocks 12 at a side of the bottom plate 11. One of the pivot shafts 70 extends through the through holes 13, the pivot hole 821, and is riveted to the blocks 12, to pivotably connect the wrench 80 to the pivot shaft 70. Use the same manner, the other pivot shaft 70 is riveted to the other two blocks 12, and the other wrench 80 is pivotably connect to the other pivot shaft 70.

The bottom plate 11 of the heat sink 10 is placed on the electronic component 21. Each hook 822 is located between the electronic component 21 and the corresponding slide post 40. A distal end of each hook 822 away from the pivot segment 82 is located at an edge of a bottom surface of the corresponding slide pole 40 near the heat sink 10. The distance from the center O of each pivot hole 821 to the bottom surface of the corresponding slide pole 40 is L. The operation poles 81 are rotated toward the heat sink 10, to allow the hooks 822 to move. The hooks 822 abut against the bottom surfaces of the slide poles 40, to make the slide poles 40 move up along the fasteners 60. The resilient members 50 are deformed. When the operation poles 81 are rotated to be perpendicular to the circuit board 20, the wrenches 80 are released. The distance from the center O of each pivot hole 821 to the bottom surface of the corresponding slide pole 40 is changed to A. Therefore, the slide poles 40 move up a distance of W, wherein W=L−A. The deformation quantity of the resilient members 50 is also W. The resilient members 50 bias the slide poles 40 to press down the hooks 822. The wrenches 80 press down the pivot shafts 70. The pivot shafts 70 press down the blocks 12, to bias the heat sink 10 to press the electronic component 21 tightly. Therefore, the heat sink 10 is fastened to the electronic component 21.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A fastening device for a heat sink, comprising:
a circuit board comprising an electronic component, and four protrusions extending up from the circuit board and located at opposite sides of the electronic component;
four fasteners engaged in the protrusions;
two slide poles located at the opposite sides of the electronic component, each slide pole slidably connected to two of the fasteners at a same side of the electronic component;
four resilient members connected to the fasteners and located above the slide poles; and
two wrenches pivotably to be connected to opposite sides of the heat sink, each wrench comprising a hook;
wherein when the wrenches are rotated, the hooks abut against bottoms of the slide poles to bias the slide poles to move up and deform the resilient members; and when the wrenches are perpendicular to the circuit board, the hooks move to bottoms of the corresponding slide poles and the slide poles press down the hooks, the wrenches make the heat sink press the electronic component.

2. The fastening device of claim 1, further comprising two pivot shafts, wherein each wrench defines a pivot hole, each pivot shaft pivotably extends through the corresponding pivot hole and is fastened between two blocks extending from a corresponding one of the opposite sides of the heat sink.

3. The fastening device of claim 2, wherein each wrench comprises an operation pole, and a pivot segment formed on a bottom end of the operation pole, the pivot hole is defined in the pivot segment.

4. The fastening device of claim 3, wherein each hook extends from the corresponding pivot segment, opposite to the corresponding operation pole.

5. The fastening device of claim 1, wherein each slide pole defines two through holes in opposite ends, a locking hole is defined in each protrusion, the fasteners slidably extend through the through holes and engage in the locking holes.

6. The fastening device of claim 1, wherein a backplane is fastened to a bottom surface of the circuit board.
